(19) United States
(12) Patent Application Publication
(10) Pub. No.: US 2025/0079232 A1
(43) Pub. Date: Mar. 6, 2025

(54) SEMICONDUCTOR PACKAGE BONDING TOOL AND SEMICONDUCTOR PACKAGE FABRICATION METHOD USING THE SAME

(71) Applicant: SAMSUNG ELECTRONICS CO., LTD., SUWON-SI (KR)

(72) Inventors: TAEJAE PARK, Suwon-si (KR); YONGKWAN LEE, Suwon-si (KR); SUNCHUL KIM, Suwon-si (KR); JUNGSOO JEON, Suwon-si (KR)

(21) Appl. No.: 18/596,869

(22) Filed: Mar. 6, 2024

(30) Foreign Application Priority Data
Sep. 5, 2023 (KR) 10-2023-0117671

(51) Int. Cl. H01L 21/687; H01L 21/48; H01L 21/67; H01L 21/683

(52) U.S. Cl. CPC H01L 21/68785; H01L 21/4817; H01L 21/67092; H01L 21/6838; H01L 21/68778

(57) ABSTRACT

A semiconductor package bonding tool includes a bonding plate and bonding blocks disposed on a bottom surface of the bonding plate. The bonding plate include first vacuum holes that vertically penetrate the bonding plate. The first vacuum holes connect a top surface of the bonding plate to the bottom surface of the bonding plate. Each of the bonding blocks includes a bonding stage disposed below a respective first vacuum hole of the first vacuum holes. The bonding stage includes a trench hole upwardly recessed from a bottom surface of the bonding stage, and a connection hole connecting a top surface of the bonding stage to the trench hole. A length in a horizontal direction of the trench hole is greater than that of the connection hole.

### CROSS-REFERENCE TO RELATED APPLICATION

This application claims priority under 35 U.S.C § 119 to Korean Patent Application No. 10-2023-0117671, filed on Sep. 5, 2023, in the Korean Intellectual Property Office, the disclosure of which is hereby incorporated by reference in its entirety.

### TECHNICAL FIELD

The present inventive concepts relate to a semiconductor package bonding tool and a semiconductor package fabrication method using the same, and more particularly, to a semiconductor package bonding tool capable of improved bonding and a semiconductor package fabrication method using the same.

### DISCUSSION OF RELATED ART

A semiconductor package may be provided to implement an integrated circuit chip for use in electronic products. In general, the semiconductor package may be fabricated by mounting a semiconductor chip on a substrate such as a printed circuit board (PCB). A single semiconductor package may include a plurality of semiconductor chips mounted on a substrate. Different semiconductor chips may have different functions. The plurality of semiconductor chips may be stacked on the substrate. Recently, a package-on-package (POP) package structure has been proposed in which a semiconductor package is stacked on another semiconductor package.

### SUMMARY

Some embodiments of the present inventive concepts provide a semiconductor package bonding tool capable of inhibiting or preventing delamination of a semiconductor chip and a substrate, and a semiconductor package fabrication method using the same.

Some embodiments of the present inventive concepts provide a semiconductor package bonding tool capable of reducing a probability of damage to a semiconductor chip and a semiconductor package fabrication method using the same.

Some embodiments of the present inventive concepts provide a semiconductor package bonding tool capable of reducing a probability of warpage of a substrate and a semiconductor package fabrication method using the same.

Some embodiments of the present inventive concepts provide a semiconductor package bonding tool capable of simultaneously fabricating a plurality of semiconductor packages and a semiconductor package fabrication method using the same.

Objects of the present inventive concepts are not limited to those mentioned herein, and other objects will be clearly understood to those skilled in the art from the following description.

According to some embodiments of the present inventive concepts, a semiconductor package bonding tool may comprise: a bonding plate; and a plurality of bonding blocks disposed on a bottom surface of the bonding plate. The bonding plate may include a plurality of first vacuum holes that vertically penetrate the bonding plate. The plurality of first vacuum holes may connect a top surface of the bonding plate to the bottom surface of the bonding plate. Each of the plurality of bonding blocks may include a bonding stage disposed below a respective first vacuum hole of the plurality of first vacuum holes. The bonding stage may include: a trench hole upwardly recessed from a bottom surface of the bonding stage, and a connection hole connecting a top surface of the bonding stage to the trench hole. A length in a horizontal direction of the trench hole may be greater than a length in the horizontal direction of the connection hole.

According to some embodiments of the present inventive concepts, a semiconductor package bonding tool may comprise: a bonding plate; and a bonding block disposed on a bottom surface of the bonding plate. The bonding plate may include a first vacuum hole that vertically penetrates the bonding plate. The bonding block may include a bonding stage disposed below the first vacuum hole. The bonding stage may include: a connection hole connected to the first vacuum hole and vertically penetrating the bonding stage; and a trench hole upwardly recessed from a bottom surface of the bonding stage. The trench hole may surround the connection hole and may be spaced apart in a horizontal direction from the connection hole.

According to some embodiments of the present inventive concepts, a semiconductor package fabrication method may comprise: placing an upper substrate on a lower package; and pressing, by a semiconductor package bonding tool, the upper substrate against the lower package. The lower package may include: a lower substrate; and a lower chip on the lower substrate. The semiconductor package bonding tool may include: a bonding plate; and a bonding stage disposed on a bottom surface of the bonding plate. The bonding plate may provide a first vacuum hole that vertically penetrates the bonding plate. The bonding stage may provide: a connection hole connected to the first vacuum hole and downwardly recessed from a top surface of the bonding stage; and a trench hole upwardly recessed from a bottom surface of the bonding stage. A length in a horizontal direction of the trench hole may be greater than a length in the horizontal direction of the lower chip, and when the upper substrate is pressed against the lower package, the trench hole may be at a position on and vertically spaced apart from an edge surface of the lower chip.

Details of example embodiments are included in the description and drawings.

### BRIEF DESCRIPTION OF DRAWINGS

FIG. 1 illustrates a cross-sectional view showing a semiconductor package bonding apparatus according to some embodiments of the present inventive concepts.

FIG. 2 illustrates a cross-sectional view showing a semiconductor package bonding tool according to some embodiments of the present inventive concepts.

FIG. 3 illustrates an exploded perspective view showing a semiconductor package bonding tool according to some embodiments of the present inventive concepts.

FIG. 4 illustrates a bottom view showing a semiconductor package bonding tool according to some embodiments of the present inventive concepts.

FIG. 5 illustrates an enlarged bottom view showing section X of FIG. 4.

FIG. 6 illustrates a flow chart showing a semiconductor package fabrication method according to some embodiments of the present inventive concepts.

FIGS. 7, 8, 9, and 10 illustrate diagrams showing a semiconductor package fabrication method according to the flow chart of FIG. 6.

FIG. 11 illustrates a cross-sectional view showing a semiconductor package fabricated by a semiconductor package fabrication method according to some embodiments of the present inventive concepts.

FIG. 12 illustrates a cross-sectional view showing a semiconductor package bonding apparatus according to some embodiments of the present inventive concepts.

FIG. 13 illustrates a cross-sectional view showing a semiconductor package bonding tool according to some embodiments of the present inventive concepts.

FIG. 14 illustrates a bottom view showing a semiconductor package bonding tool according to some embodiments of the present inventive concepts.

FIG. 15 illustrates an enlarged bottom view showing section X′ of FIG. 14.

FIG. 16 illustrates a cross-sectional view showing a semiconductor package placed on a semiconductor package bonding apparatus according to some embodiments of the present inventive concepts.

FIG. 17 illustrates an enlarged cross-sectional view showing section Y′ of FIG. 16.

### DETAILED DESCRIPTION

Embodiments of the present inventive concepts are described with reference to the accompanying drawings. Like reference numerals may indicate like components throughout the description.

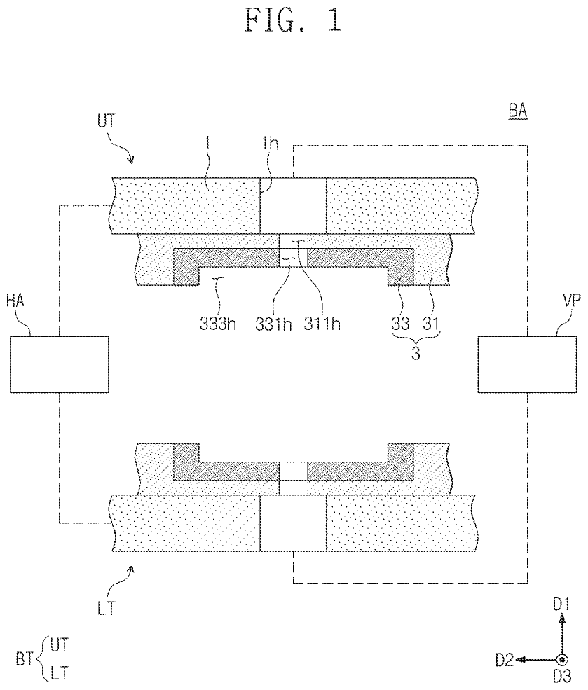

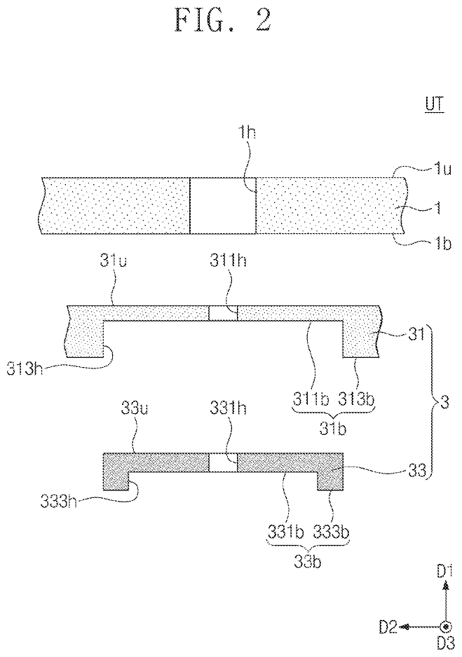

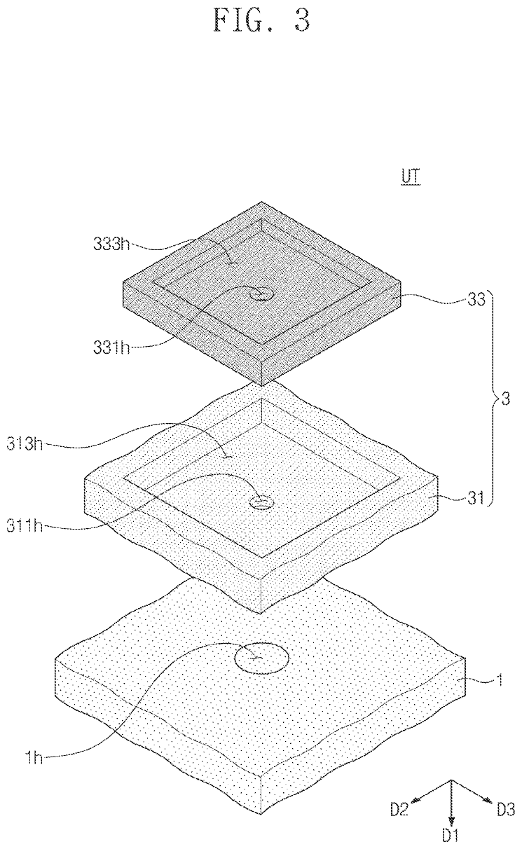

FIG. 1 illustrates a cross-sectional view showing a semiconductor package bonding apparatus according to some embodiments of the present inventive concepts. FIG. 2 illustrates a cross-sectional view showing a semiconductor package bonding tool according to some embodiments of the present inventive concepts. FIG. 3 illustrates an exploded perspective view showing a semiconductor package bonding tool according to some embodiments of the present inventive concepts.

In this description, label D1 may indicate a first direction, label D2 may indicate a second direction that intersects the first direction D1, and label D3 may indicate a third direction that intersects each of the first direction D1 and the second direction D2. The first direction D1 may be called an upward direction or a vertical direction. In addition, each of the second direction D2 and the third direction D3 may be called a horizontal direction. For example, the second direction D2 and the third direction D3 may form a plane, and the first direction D1 may be disposed perpendicular to the plane formed by the second direction D2 and the third direction D3.

Referring to FIGS. 1, 2, and 3, a semiconductor package bonding apparatus BA may be provided. The semiconductor package bonding apparatus BA may be a device configured to fabricate a semiconductor package. The semiconductor package bonding apparatus BA may be a device configured to perform a thermo-compression (TC) bonding process. For example, the semiconductor package bonding apparatus BA may be configured to use a thermo-compression bonding process to bond a substrate to a lower package. The semiconductor package bonding apparatus BA may include a semiconductor package bonding tool BT, a vacuum pump VP, and a heating device HA. The semiconductor package bonding tool BT may include a first semiconductor package bonding tool UT and a second semiconductor package bonding tool LT.

The semiconductor package bonding tool BT may fixedly hold a lower package and/or a semiconductor chip at a certain location. In addition, the semiconductor package bonding tool BT may move or press a substrate. The semiconductor package bonding tool BT may include a plurality of tools. For example, semiconductor package bonding tool BT include the first semiconductor package bonding tool UT and the second semiconductor package bonding tool LT. The first semiconductor package bonding tool UT and the second semiconductor package bonding tool LT may be different tools or different portions of a same tool.

The first semiconductor package bonding tool UT may be disposed on the second semiconductor package bonding tool LT. The first semiconductor package bonding tool UT may include a bonding plate 1 and a bonding block 3.

The bonding plate 1 may have, for example, a plate shape that is perpendicular to the first direction D1. The bonding plate 1 may have a rectangular shape, but the present inventive concepts are not limited thereto. The bonding plate 1 may provide a first vacuum hole 1h. The first vacuum hole 1h may extend through the bonding plate 1. For example, the first vacuum hole 1h may extend through the bonding plate 1. The first vacuum hole 1h may connect a top surface 1u of the bonding plate 1 to a bottom surface 1b of the bonding plate 1 (see FIG. 2). For example, the first vacuum hole 1h may penetrate in the first direction D1 through the bonding plate 1. For example, the first vacuum hole 1h may be exposed at the top surface 1u and the bottom surface 1b of the bonding plate 1. The first vacuum hole 1h will be further discussed in detail herein.

The bonding block 3 may be positioned on the bottom surface 1b of the bonding plate 1. The bonding block 3 may include a block body 31 and a bonding stage 33.

The block body 31 may be positioned between the bonding plate 1 and the bonding stage 33. For example, the block body 31 may be coupled to the bottom surface 1b of the bonding plate 1. The block body 31 may be formed of a ceramic, but the present inventive concepts are not limited thereto. The block body 31 may include a vacuum transfer hole 311h and a placement hole 313h.

The vacuum transfer hole 311h may downwardly extend from a top surface 31u of the block body 31. The vacuum transfer hole 311h may be connected to a bottom surface 31b of the block body 31. For example, the vacuum transfer hole 311h may be exposed at the top surface 31u and the bottom surface 31b of the block body 31. For example, the vacuum transfer hole 311h may be connected to a first bottom surface 311b of the block body 31. The vacuum transfer hole 311h may be aligned to the first vacuum hole 1h. For example, the vacuum transfer hole 311h may be connected to the first vacuum hole 1h.

The placement hole 313h may be formed upwardly recessed from the bottom surface 31b of the block body 31. The placement hole 313h may define the first bottom surface 311b of the block body 31. A second bottom surface 313b may surround the first bottom surface 311b of the block body 31. The bonding stage 33 may be inserted into the placement hole 313h. The placement hole 313h may have a tetragonal shape. For example, the placement hole 313h may have a rectangular shape. The present inventive concepts, however, are not limited thereto. For example, the placement hole 313h may have an isometric shape or a hexagonal shape.

The bonding stage 33 may be positioned below the bonding plate 1. The bonding stage 33 may be coupled to the block body 31. For example, the bonding stage 33 may be inserted into the placement hole 313h. The bonding stage 33 may be formed of a ceramic, but the present inventive concepts are not limited thereto. The bonding stage 33 may provide a connection hole 331h and a trench hole 333h.

The connection hole 331h may downwardly extend from a top surface 33u of the bonding stage 33. The connection hole 331h may connect the top surface 33u of the bonding stage 33 to a bottom surface 33b of the bonding stage 33. For example, the connection hole 331h may be exposed at the top surface 33u and the bottom surface 33b of the bonding stage 33. For example, the connection hole 331h may vertically penetrate the bonding stage 33 and connect the top surface 33u of the bonding stage 33 to a first bottom surface 331b of the bonding stage 33. The connection hole 331h may be connected to the vacuum transfer hole 311h. The vacuum transfer hole 311h of the block bodies 31 may have a same shape as the connection hole 331h of the bonding stage 33. Embodiments of the present inventive concepts are not limited thereto, for example, the vacuum transfer hole 311h of the block bodies 31 may have a different shape than the connection hole 331h of the bonding stage 33. The connection hole 331h may be aligned to the vacuum transfer hole 311h and the first vacuum hole 1h. For example, the connection hole 331h may be connected through the vacuum transfer hole 311h to the first vacuum hole 1h. For example, the vacuum transfer hole 311h may be positioned between the first vacuum hole 1h and the connection hole 331h.

A width of the connection hole 331h may be less than a width of the first vacuum hole 1h. A width of the vacuum transfer hole 311h may be less than the width of the first vacuum hole 1h. The width of the vacuum transfer hole 311h may be the same as the width of the connection hole 331h, but the present inventive concepts are not limited thereto. For example, the width of the vacuum transfer hole 311h may be greater than the width of the connection hole 331h.

The trench hole 333h may be formed upwardly recessed from the bottom surface 33b of the bonding stage 33. The trench hole 333h may define the first bottom surface 331b of the bonding stage 33. A second bottom surface 333b may surround the first bottom surface 331b of the bonding stage 33. The trench hole 333h may be connected to the connection hole 331h. The trench hole 333h may have a tetragonal shape. For example, the trench hole 333h may have a rectangular shape. The present inventive concepts, however, are not limited thereto. A length in the horizontal direction of the trench hole 333h may be greater than a length in the horizontal direction of the connection hole 331h. A detailed description thereof will be further discussed below.

When the bonding stage 33 is coupled to the block body 31, the second bottom surface 333b of the bonding stage 33 may be positioned on a same plane as that of the second bottom surface 313b of the block body 31, but the present inventive concepts are not limited thereto. For example, the second bottom surface 333b of the bonding stage 33 and the second bottom surface 313b of the block body 31 may form a plane, the second bottom surface 333b of the bonding stage 33 may be positioned above the second bottom surface 313b of the block body 31, or the second bottom surface 333b of the bonding stage 33 may be positioned below the second bottom surface 313b of the block body 31.

The second semiconductor package bonding tool LT may be disposed below the first semiconductor package bonding tool UT. The second semiconductor package bonding tool LT may be disposed opposite to the first semiconductor package bonding tool UT, for example, where a work surface of the second semiconductor package bonding tool LT may face a work surface the first semiconductor package bonding tool UT. Here, a work surface may be, for example, a surface that supports an element to be bonded. The second semiconductor package bonding tool LT may have a structure the same as or similar to that of the first semiconductor package bonding tool UT.

The vacuum pump VP may apply a vacuum pressure to the semiconductor package bonding tool BT. For example, the vacuum pump VP may be connected to the first vacuum hole 1h of the first semiconductor package bonding tool UT to apply a vacuum pressure to the first vacuum hole 1h. Similarly, the vacuum pump VP may be connected to a vacuum hole of the second semiconductor package bonding tool LT.

FIG. 1 illustrates an example in which the vacuum pump VP is connected to the first vacuum hole 1h of the first semiconductor package bonding tool UT and a vacuum hole of the second semiconductor package bonding tool LT, however, the present inventive concepts are not limited thereto. For example, two or more vacuum pumps VP may be connected to the first vacuum hole 1h of the first semiconductor package bonding tool UT and the second semiconductor package bonding tool LT. Further, different vacuum pumps VP may be separately connected to the first vacuum hole 1h of the first semiconductor package bonding tool UT and the vacuum hole of the second semiconductor package bonding tool LT, respectively.

The heating device HA may transfer heat to the semiconductor package bonding tool BT. For example, the heating device HA may use thermal conduction to heat the bonding plate 1 of the first semiconductor package bonding tool UT. Similarly, the heating device HA may be connected to a bonding plate of the second semiconductor package bonding tool LT.

FIG. 1 illustrates an example in which the heating device HA is connected to the first semiconductor package bonding tool UT and the second semiconductor package bonding tool LT, however, the present inventive concepts are not limited thereto. For example, two or more heating devices HA may be connected to the first semiconductor package bonding tool UT and the second semiconductor package bonding tool LT. Further, different heating devices HA may be separately connected to the first semiconductor package bonding tool UT and the second semiconductor package bonding tool LT, respectively.

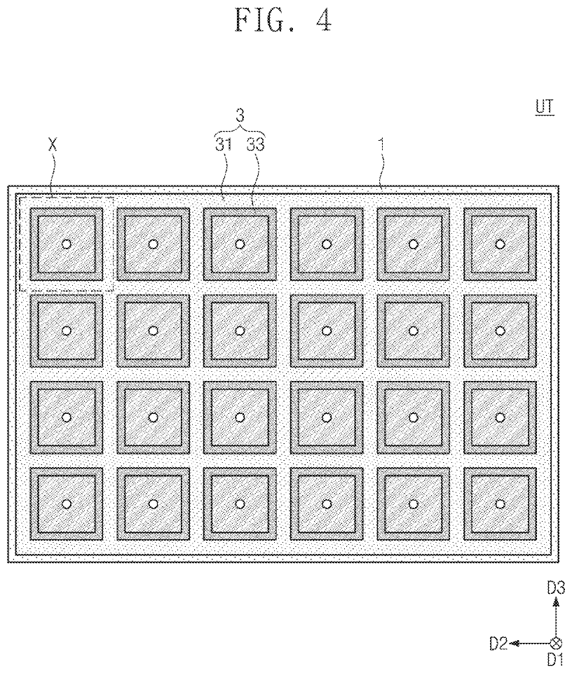

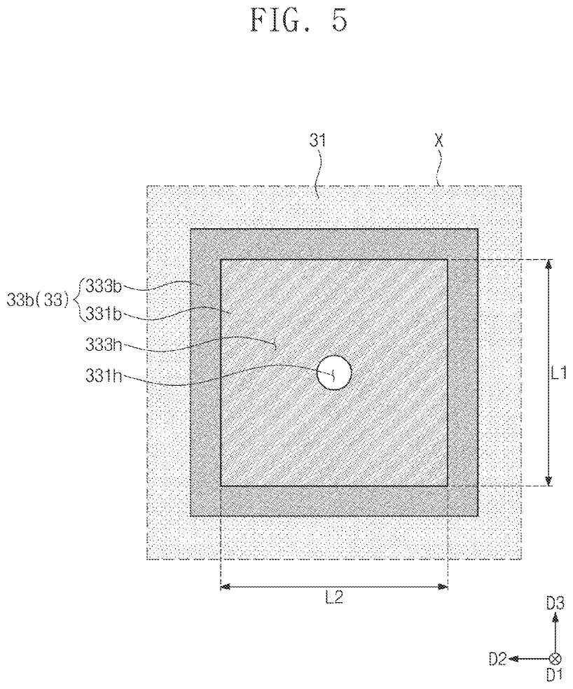

FIG. 4 illustrates a bottom view showing a semiconductor package bonding tool according to some embodiments of the present inventive concepts. FIG. 5 illustrates an enlarged bottom view showing section X of FIG. 4 in a plan view.

Referring to FIG. 4, the bonding block 3 may be one of a plurality of bonding blocks. Thus, the block body 31 and the bonding stage 33 may be instances in larger groups. The plurality of bonding blocks 3 may be arranged in the horizontal direction on the bottom surface (see bottom surface 1b of FIG. 2) of the bonding plate 1. The plurality of bonding blocks 3 may be arranged in an array on the bottom surface of the bonding plate 1 in the second horizontal direction D2 and the third horizontal direction D3. The plurality of block bodies 31 may be integrally connected into a single unitary piece, as shown in FIG. 4. For example, the plurality of block bodies 31 may form one plate body. The present inventive concepts, however, are not limited thereto, and the plurality of block bodies 31 may be disposed spaced apart from each other. By way of example, a single bonding block 3 will be discussed herein.

Referring to FIG. 5, a first length L1 may indicate a length in the third direction D3 of the trench hole 333h. A second length L2 may indicate a length in the second direction D2 of the trench hole 333h. The first length L1 may range, for example, from about 5 mm to about 15 mm. The second length L2 may range, for example, from about 5 mm to about 15 mm. The first length L1 and the second length L2 may be the same as each other, but the present inventive concepts are not limited thereto. For example, in a plan view, the trench hole 333h may be a square, a rectangle, or another shape.

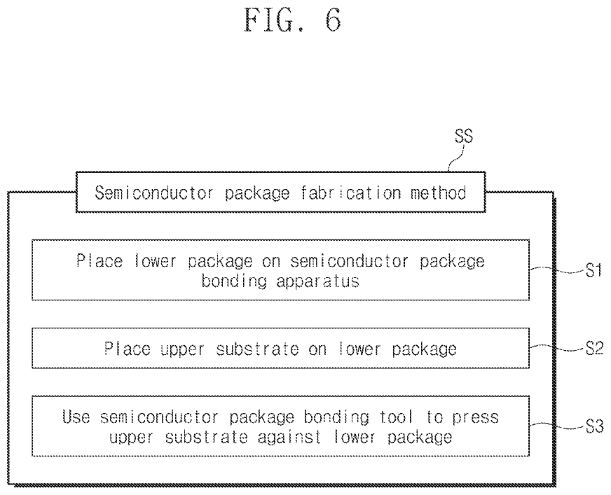

FIG. 6 illustrates a flow chart showing a semiconductor package fabrication method according to some embodiments of the present inventive concepts.

Referring to FIG. 6, a semiconductor package fabrication method SS may be provided. The semiconductor package fabrication method SS may be a way of fabricating a semiconductor package by using the semiconductor package bonding apparatus (see semiconductor package bonding apparatus DA of FIG. 1) discussed with reference to FIGS. 1, 2, 3, 4, and 5. For example, the semiconductor package fabrication method SS may be a method of bonding a substrate to a lower package. The semiconductor package fabrication method SS may include placing a lower package on a semiconductor package bonding apparatus (S1), placing an upper substrate on the lower package (S2), and using a semiconductor package bonding tool to press the upper substrate against the lower package (S3). Similarly, the semiconductor package bonding tool may press the upper substrate and the lower package together, or press the lower package against the upper substrate (S3).

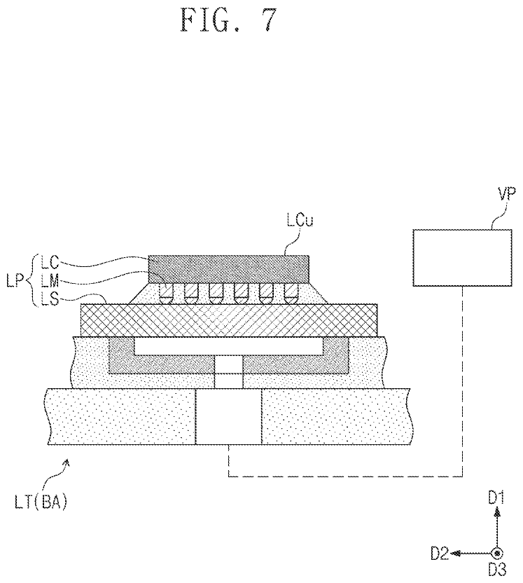

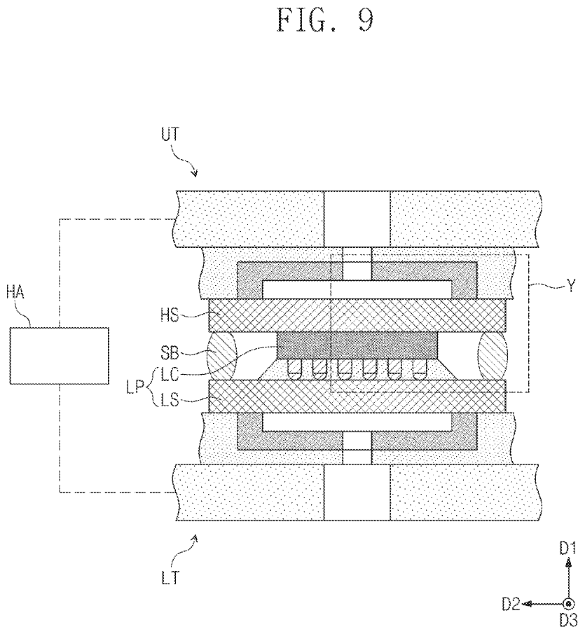

The semiconductor package fabrication method SS of FIG. 6 will be further discussed with reference to FIGS. 7, 8, 9, and 10.

FIGS. 7, 8, 9, and 10 illustrate a semiconductor package fabrication method according to the flow chart of FIG. 6.

Referring to FIG. 6 and FIG. 7, a package placement step S1 may include placing a lower package LP on the second semiconductor package bonding tool LT. The lower package LP may include a lower substrate LS, a lower chip LC, and a connection member LM. The lower substrate LS may include a printed circuit board (PCB), but the present inventive concepts are not limited thereto. A vacuum pressure provided from the vacuum pump VP may fixedly hold the lower substrate LS to a certain location on the second semiconductor package bonding tool LT. The lower chip LC may be positioned on the lower substrate LS. The lower chip LC may include, for example, one or more of a logic chip and a memory chip. The connection member LM may electrically connect the lower substrate LS to the lower chip LC. The connection member LM may include one or more of solder balls and copper fillers, but the present inventive concepts are not limited thereto. A top surface LCu of the lower chip LC may be exposed. For example, the top surface LCu of the lower chip LC may be exposed after a package placement step S1.

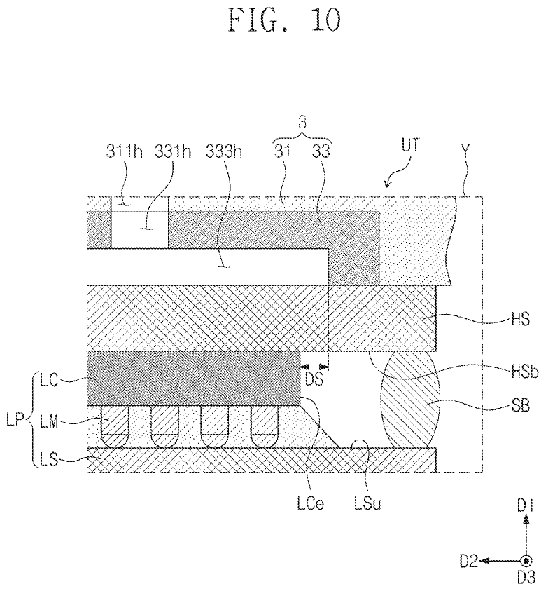

Referring to FIGS. 6, 8, and 9, a substrate placement step S2 may be performed by the first semiconductor package bonding tool UT. The first semiconductor package bonding tool UT may cause an upper substrate HS to move to a location on the lower package LP. For example, a vacuum pressure provided from the vacuum pump VP may couple the upper substrate HS to a bottom surface of the bonding stage 33 of the first semiconductor package bonding tool UT. A vacuum pressure provided from the vacuum pump VP may be transferred through the first vacuum hole 1h, the vacuum transfer hole 311h, the connection hole 331h, and/or the trench hole 333h to a top surface of the upper substrate HS. Therefore, the upper substrate HS may be fixed to the bonding stage 33. The upper substrate HS may include a printed circuit board (PCB), but the present inventive concepts are not limited thereto. A solder ball SB may be bonded to a bottom surface HSb of the upper substrate HS. For example, the lower package LP may be provided thereon with the upper substrate HS to which the solder ball SB may be bonded. The solder ball SB may be provided on a top surface (see top surface LSu of FIG. 10) of the lower substrate LS.

Referring to FIGS. 6, 9, and 10, a press step S3 may include allowing the first semiconductor package bonding tool UT to downwardly press the upper substrate HS. The upper substrate HS may be heated through the bonding stage 33. For example, heat that the heating device HA applies to the first semiconductor package bonding tool UT may be transferred through the bonding stage 33 to the upper substrate HS. Thus, the upper substrate HS and the solder ball SB may increase in temperature. The solder ball SB may be bonded to the lower substrate LS. In this procedure, the bottom surface HSb of the upper substrate HS and a top surface of the lower chip LC may be in contact with each other as shown in FIG. 10, but the present inventive concepts are not limited thereto. For example, the bottom surface HSb of the upper substrate HS may be upwardly spaced apart from the top surface of the lower chip LC.

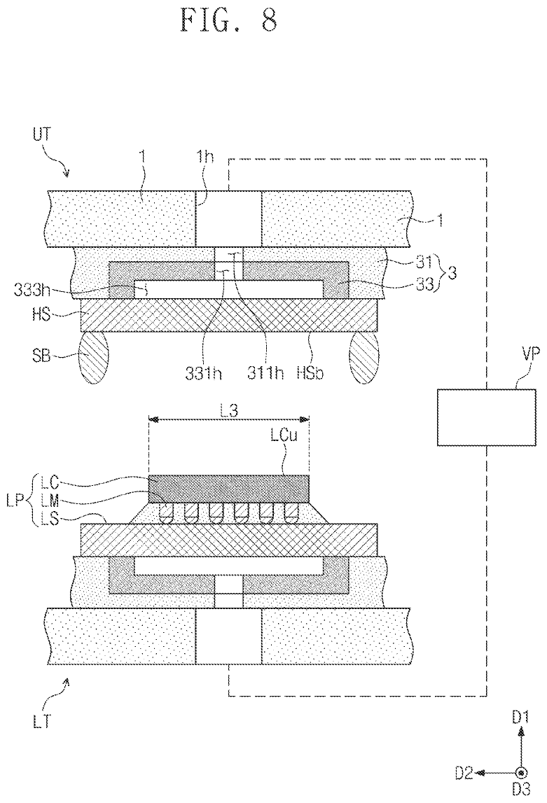

An extent of the trench hole 333h in the horizontal directions may be greater than an extent of the lower chip LC in the second horizontal direction D2 and the third horizontal direction D3. For example, dimensions of the trench hole 333h in the horizontal directions may be greater than dimensions of the lower chip LC in the horizontal directions (see L3 of FIG. 8). For example, an edge of the trench hole 333h may be spaced apart from, and outward of an edge surface LCe of the lower chip LC by a distance DS.

In a press step S3, the trench hole 333h may be disposed at a position on and vertically spaced apart from the edge surface LCe of the lower chip LC. For example, the trench hole 333h may cover the edge surface LCe of the lower chip LC. When the lower chip LC has a tetragonal shape, the lower chip LC may have four edge surfaces LCe. The trench hole 333h may cover all edge surfaces LCe. For example, the trench hole 333h may be disposed at a position on and vertically spaced apart from each of the edge surfaces LCe.

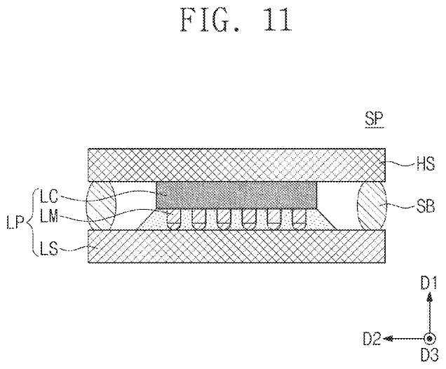

FIG. 11 illustrates a cross-sectional view showing a semiconductor package fabricated by a semiconductor package fabrication method according to some embodiments of the present inventive concepts.

Referring to FIG. 11, the lower substrate LS and the upper substrate HS may be electrically connected through the solder ball SB.

According to a semiconductor package bonding tool and a semiconductor package fabrication method using the same in accordance with some embodiments of the present inventive concepts, when an upper substrate is pressed against a lower package, a trench hole may cover an edge surface of a lower chip. For example, at a position on and vertically spaced apart from the edge surface of the lower chip, a bonding stage may not be in contact with the upper substrate and a reduction in heat and/or pressure applied to the edge surface of the lower chip may be achieved, and damage to the edge surface of the lower chip may be reduced or prevented. In a case where a reduction in heat and/or pressure applied to the edge surface of the lower chip may be achieved, delamination of the edge surface of the lower chip from the upper substrate and/or a lower substrate may be reduced or prevented. In some cases, a manufacturing yield for a semiconductor package may be increased by decreasing or preventing damage to the edge surface of the lower chip and/or reducing delamination of the edge surface of the lower chip.

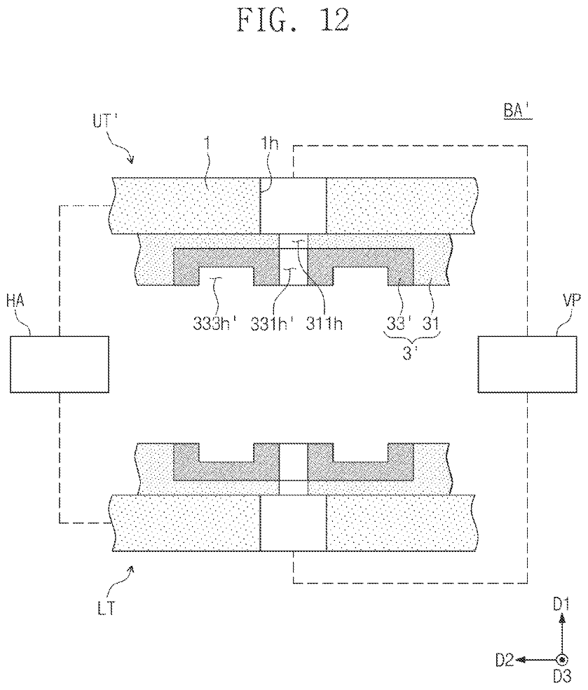

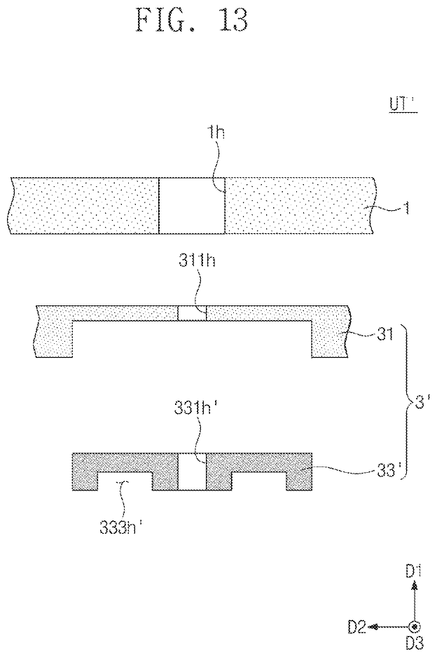

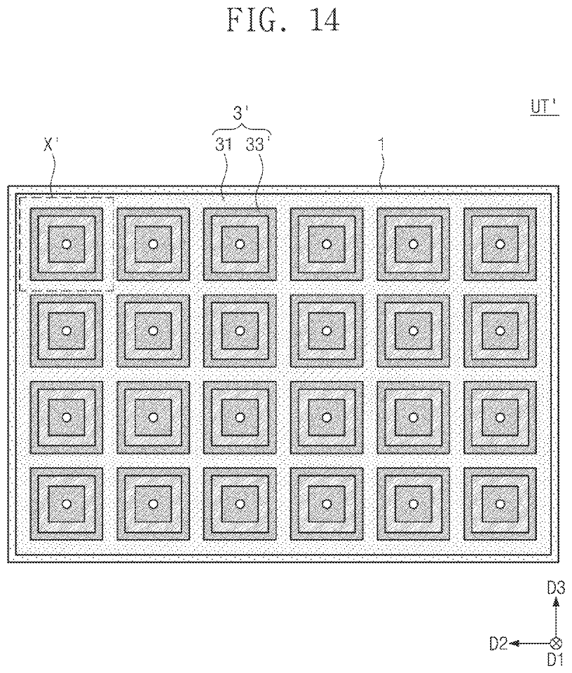

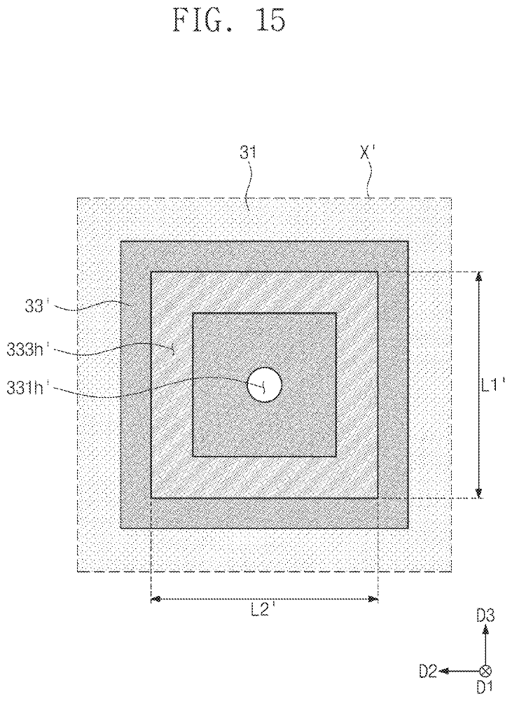

FIG. 12 illustrates a cross-sectional view showing a semiconductor package bonding apparatus according to some embodiments of the present inventive concepts. FIG. 13 illustrates a cross-sectional view showing a semiconductor package bonding tool according to some embodiments of the present inventive concepts. FIG. 14 illustrates a bottom view showing a semiconductor package bonding tool according to some embodiments of the present inventive concepts. FIG. 15 illustrates an enlarged bottom view showing section X′ of FIG. 14.

In the drawings, the same reference numerals may refer to the same elements, and any further repetitive description concerning the elements may be omitted.

Referring to FIGS. 11, 12, 13, 14, and 15, a semiconductor package bonding apparatus BA′ may include a first semiconductor package bonding tool UT′, a second semiconductor package bonding tool LT, a vacuum pump VP, and a heating device HA.

The first semiconductor package bonding tool UT′ may include a bonding plate 1 and a bonding block 3′. The bonding block 3′ may be disposed on the bonding plate 1.

The bonding block 3′ may include a block body 31 and a bonding stage 33′. The bonding stage 33′ may be disposed on the block body 31.

The bonding stage 33′ may provide a connection hole 331h′ and a trench hole 333h′. The trench hole 333h′ may be disposed around the connection hole 331h′.

The connection hole 331h′ may vertically penetrate the bonding stage 33′. The connection hole 331h′ may be aligned with the first vacuum hole 1h. The connection hole 331h′ may be connected to the first vacuum hole 1h.

The trench hole 333h′ may be formed upwardly recessed from a bottom surface of the bonding stage 33′. The trench hole 333h′ may surround the connection hole 331h′. The trench hole 333h′ may be spaced apart in the second horizontal direction D2 and the third horizontal direction D3 from the connection hole 331h′. For example, a portion of the bonding stage 33′ may separate the trench hole 333h′ from the connection hole 331h′. Thus, the trench hole 333h′ may not be connected to the connection hole 331h′. The trench hole 333h′ may have, for example, a tetragonal frame shape. The trench hole 333h′ may not be connected to the first vacuum hole 1h. A thickness in the vertical direction of the trench hole 333h′ may be less than a thickness in the vertical direction of the bonding stage 33′. Therefore, the trench hole 333h′ may not be connected to a top surface of the bonding stage 33′.

A third length L1′ (see FIG. 15) may indicate a length in the third horizontal direction D3 of the trench hole 333h′. A fourth length L2′ may indicate a length in the second horizontal direction D2 of the trench hole 333h′. The third length L1′ may range, for example, from about 5 millimeters (mm) to about 15 mm. The fourth length L2′ may range, for example, from about 5 mm to about 15 mm. The third length L1′ and the fourth length L2′ may be the same as each other, but the present inventive concepts are not limited thereto.

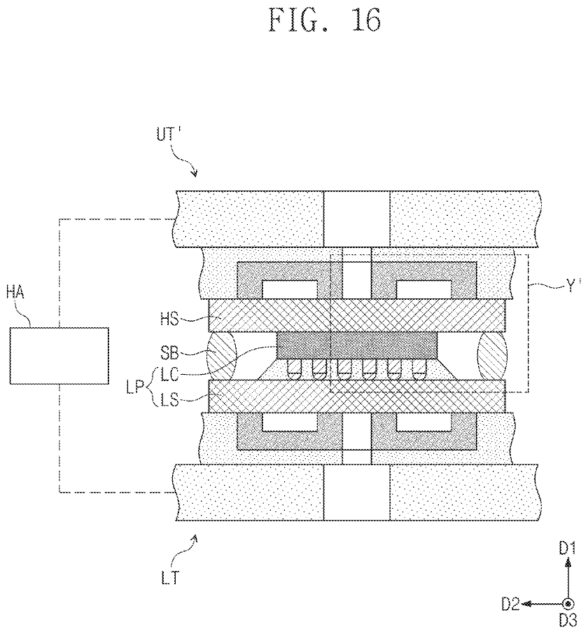

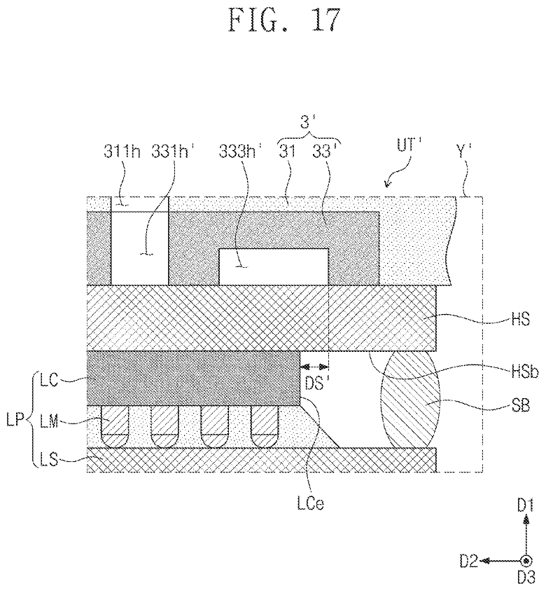

FIG. 16 illustrates a cross-sectional view showing a semiconductor package disposed on a semiconductor package bonding apparatus according to some embodiments of the present inventive concepts. FIG. 17 illustrates an enlarged cross-sectional view showing section Y′ of FIG. 16.

Referring to FIG. 16 and FIG. 17, lengths of the trench hole 333h′ in the second direction D2 and the third direction D3 may be greater than lengths of the lower chip LC the second direction D2 and the third direction D3. For example, an edge of the trench hole 333h′ may be spaced apart from, and outward of the edge surface LCe of the lower chip LC by a distance DS.

In a press step S3, the trench hole 333h′ may be disposed at a position on and vertically spaced apart from the edge surface LCe of the lower chip LC. For example, the trench hole 333h′ may cover the edge surface LCe of the lower chip LC. When the lower chip LC has a tetragonal shape, the lower chip LC may have four edge surfaces LCe. The trench hole 333h′ may cover all edge surfaces LCe. For example, the trench hole 333h′ may be disposed at a position on and vertically spaced apart from each of the edge surfaces LCe.

According to a semiconductor package bonding tool and a semiconductor package fabrication method using the same in accordance with some embodiments of the present inventive concepts, when an upper substrate is pressed against a lower package, a trench hole may cover an edge surface of a lower chip and a reduction in heat and/or pressure applied to the edge surface of the lower chip may be achieved. In addition, when the trench hole overlaps the edge surface of the lower chip, a bonding stage may press the upper substrate against the lower chip, and the lower chip may be uniformly pressed and heated.

According to a semiconductor package bonding tool and a semiconductor package fabrication method using the same of the present inventive concepts, delamination of a semiconductor chip and a substrate in fabrication process may be inhibited or prevented.

According to a semiconductor package bonding tool and a semiconductor package fabrication method using the same of the present inventive concepts, damage to a semiconductor chip in fabrication process may be reduced or prevented.

According to a semiconductor package bonding tool and a semiconductor package fabrication method using the same of the present inventive concepts, warpage of a substrate in fabrication process may be reduced or prevented.

According to a semiconductor package bonding tool and a semiconductor package fabrication method using the same of the present inventive concepts, a plurality of semiconductor package may be fabricated at once.

Effects of the present inventive concepts are not limited to those mentioned herein, and other effects will be clearly understood to those skilled in the art from the description.

Although the present inventive concepts have been described in connection with some embodiments of the present inventive concepts illustrated in the accompanying drawings, it will be understood to those skilled in the art that various changes and modifications may be made without departing from the technical spirit and features of the present inventive concepts. It therefore will be understood that embodiments described herein are illustrative, but not limitative in all aspects.

What is claimed is:

1. A semiconductor package bonding tool, comprising:
a bonding plate; and
a plurality of bonding blocks disposed on a bottom surface of the bonding plate,
wherein the bonding plate includes a plurality of first vacuum holes that vertically penetrate the bonding plate, the plurality of first vacuum holes connecting a top surface of the bonding plate to the bottom surface of the bonding plate,
wherein each of the plurality of bonding blocks includes a bonding stage disposed below a respective first vacuum hole of the plurality of first vacuum holes, and
wherein the bonding stage includes:
a trench hole upwardly recessed from a bottom surface of the bonding stage; and
a connection hole connecting a top surface of the bonding stage to the trench hole; and
wherein a length in a horizontal direction of the trench hole is greater than a length in the horizontal direction of the connection hole.

2. The semiconductor package bonding tool of claim 1, wherein the trench hole has a rectangular shape in a plan view.

3. The semiconductor package bonding tool of claim 1, wherein the length of the trench hole is in a range of about 5 mm to about 15 mm.

4. The semiconductor package bonding tool of claim 1, wherein the plurality of bonding blocks are arranged in the horizontal direction on the bottom surface of the bonding plate.

5. The semiconductor package bonding tool of claim 1, wherein each of the plurality of bonding blocks further includes a block body disposed between the bonding stage and the bonding plate,
wherein the block body includes a vacuum transfer hole connecting the first vacuum hole to the connection hole.

6. The semiconductor package bonding tool of claim 5, wherein the block bodies of the plurality of bonding blocks are integrally connected to form a plate body.

7. The semiconductor package bonding tool of claim 1, wherein the bonding stage includes a ceramic.

8. A semiconductor package bonding tool, comprising:
a bonding plate; and
a bonding block disposed on a bottom surface of the bonding plate,
wherein the bonding plate includes a first vacuum hole that vertically penetrates the bonding plate,
wherein the bonding block includes a bonding stage disposed below the first vacuum hole, and
wherein the bonding stage includes:
a connection hole connected to the first vacuum hole and vertically penetrating the bonding stage; and
a trench hole upwardly recessed from a bottom surface of the bonding stage, and
wherein the trench hole surrounds the connection hole and is spaced apart in a horizontal direction from the connection hole.

9. The semiconductor package bonding tool of claim 8, wherein the trench hole has a tetragonal frame shape.

10. The semiconductor package bonding tool of claim 8, wherein the trench hole is not connected to the first vacuum hole, and
wherein a portion of the bonding stage separates the trench hole and the connection hole.

11. The semiconductor package bonding tool of claim 8, wherein a thickness in a vertical direction of the trench hole is less than a thickness in the vertical direction of the bonding stage.

12. The semiconductor package bonding tool of claim 8, wherein a length in the horizontal direction of the trench hole is in a range of about 5 mm to about 15 mm.

13. The semiconductor package bonding tool of claim 8, further comprising:
a plurality of bonding stages including the bonding stage, and
the plurality of bonding stages are spaced apart from each other in the horizontal direction on the bottom surface of the bonding plate.

14. The semiconductor package bonding tool of claim 8, wherein a width of the connection hole is less than a width of the first vacuum hole.

15. A semiconductor package fabrication method, comprising:
placing an upper substrate on a lower package; and
pressing, by a semiconductor package bonding tool, the upper substrate against the lower package,
wherein the lower package includes:
a lower substrate; and
a lower chip on the lower substrate,
wherein the semiconductor package bonding tool includes:
a bonding plate; and
a bonding stage disposed on a bottom surface of the bonding plate,
wherein the bonding plate provides a first vacuum hole that vertically penetrates the bonding plate,
wherein the bonding stage provides:
a connection hole connected to the first vacuum hole and downwardly recessed from a top surface of the bonding stage; and
a trench hole upwardly recessed from a bottom surface of the bonding stage,
wherein a length in a horizontal direction of the trench hole is greater than a length in the horizontal direction of the lower chip, and when the upper substrate is pressed against the lower package, the trench hole is at a position on and vertically spaced apart from an edge surface of the lower chip.

16. The semiconductor package fabrication method of claim 15, wherein the lower chip has a tetragonal shape defining edge surfaces of the lower chip,
wherein, when the upper substrate is pressed against the lower package, the trench hole is at a position on and vertically spaced apart from each of the edge surfaces of the lower chip.

17. The semiconductor package fabrication method of claim 15, wherein the connection hole is connected to the trench hole,
wherein the method further comprises applying a vacuum pressure coupling a top surface of the upper substrate to the bottom surface of the bonding stage, the vacuum pressure being transferred through the first vacuum hole, the connection hole, and the trench hole.

18. The semiconductor package fabrication method of claim 15, wherein
the connection hole vertically penetrates the bonding stage to connect the top surface of the bonding stage to the bottom surface of the bonding stage,
the trench hole surrounds the connection hole and is spaced apart in the horizontal direction from the connection hole, and
wherein the method further comprises applying a vacuum pressure coupling a top surface of the upper substrate to the bottom surface of the bonding stage, the vacuum pressure being transferred through the first vacuum hole and the connection hole.

19. The semiconductor package fabrication method of claim 15, pressing the upper substrate against the lower package includes heating the upper substrate through the bonding stage.

20. The semiconductor package fabrication method of claim 19, wherein
placing the upper substrate on the lower package includes allowing a solder ball to contact the lower substrate by placing the upper substrate on the lower package where the solder ball is bonded to a bottom surface of the upper substrate, and
pressing the upper substrate against the lower package further includes allowing heat to bond the solder ball to the lower substrate, the heat being transferred to the upper substrate.
